(19) United States
(12) Patent Application Publication
(10) Pub. No.: US 2025/0119059 A1
(43) Pub. Date: Apr. 10, 2025

(54) DYNAMIC CIRCUIT CALIBRATION DURING VOLTAGE CHANGE TRANSITIONS

(71) Applicant: Qualcomm Incorporated, San Diego, CA (US)

(72) Inventors: Boris Dimitrov ANDREEV, San Diego, CA (US); Farrukh AQUIL, San Diego, CA (US); Vikas MAHENDIYAN, San Diego, CA (US); Yong XU, San Diego, CA (US); Satish KRISHNAMOORTHY, San Diego, CA (US)

(21) Appl. No.: 18/481,657

(22) Filed: Oct. 5, 2023

(51) Int. Cl. H02M 3/04; H04W 52/02

(52) U.S. Cl. CPC H02M 3/04; H04W 52/02

(57) ABSTRACT

In some aspects, an electronic device may detect a start of a voltage ramp transition period associated with changing a voltage at which an integrated circuit operates from a first voltage to a second voltage, wherein changing the voltage from the first voltage to the second voltage causes changes to one or more parameters that impact performance associated with the integrated circuit during the voltage ramp transition period. The electronic device may trigger, responsive to detecting the start of the voltage ramp transition period, a dynamic calibration mode that compensates for the changes to the one or more parameters that impact the performance associated with the integrated circuit during the voltage ramp transition period. The electronic device may exit the dynamic calibration mode responsive to detecting an end of the voltage ramp transition period. Numerous other aspects are described.

### FIELD OF THE DISCLOSURE

Aspects of the present disclosure generally relate to integrated circuits and, for example, to dynamic circuit calibration during voltage change transitions.

### BACKGROUND

Dynamic voltage and frequency scaling (DVFS), interchangeably referred to as dynamic voltage and frequency switching, dynamic clock and voltage scaling, or dynamic clock and voltage switching (DCVS), includes techniques that are used to adjust power and/or speed settings for one or more processors, controller chips, and/or peripheral devices of an electronic device to optimize resource allocations for one or more tasks and/or to maximize power savings when resources are not needed. For example, a synchronous digital circuit (e.g., a memory device, a central processing unit (CPU), or a digital signal processor (DSP)) requires a clock signal to coordinate timing of logic in the circuit. A frequency of the clock signal controls a switching speed or rate of the logic, and thus the performance of the circuit, and the clock frequency of the circuit may be related to a voltage level powering the circuit. For example, an increase in the clock frequency causes a corresponding increase in a minimum voltage level required to power the circuit for proper operation. Accordingly, an increase in clock frequency generally results in increased power consumption. Power consumption of the circuit can be decreased by lowering the voltage level. However, reducing the voltage level decreases a maximum clock frequency that is possible for the circuit. The voltage level can be reduced to a minimum level necessary for proper operation of the circuit at a desired clock frequency. Accordingly, to optimize power consumption while still providing acceptable performance, DVFS or DCVS techniques can be employed in processor-based electronic devices, including user-based portable electronic devices. DVFS or DCVS circuits control clock frequency and voltage level settings by configuring optimal clock frequency and voltage settings for a processor and/or other synchronously clocked components based on performance demands of the electronic device. In this manner, DVFS or DCVS circuits may optimize power consumption required for a demanded performance level. Further information such as temperature, battery level, and operating system scheduler state can also be used to influence the manner in which DVFS or DCVS circuits operate.

### SUMMARY

In some implementations, an electronic device includes one or more memories; and one or more processors, coupled to the one or more memories, configured to cause the electronic device to: detect a start of a voltage ramp transition period associated with changing a voltage at which an integrated circuit operates from a first voltage to a second voltage, wherein changing the voltage from the first voltage to the second voltage causes changes to one or more parameters that impact performance associated with the integrated circuit during the voltage ramp transition period; trigger, responsive to detecting the start of the voltage ramp transition period, a dynamic calibration mode that compensates for the changes to the one or more parameters that impact the performance associated with the integrated circuit during the voltage ramp transition period; and exit the dynamic calibration mode responsive to detecting an end of the voltage ramp transition period.

In some implementations, a method performed by an electronic device includes detecting a start of a voltage ramp transition period associated with changing a voltage at which an integrated circuit operates from a first voltage to a second voltage, wherein changing the voltage from the first voltage to the second voltage causes changes to one or more parameters that impact performance associated with the integrated circuit during the voltage ramp transition period; triggering, responsive to detecting the start of the voltage ramp transition period, a dynamic calibration mode that compensates for the changes to the one or more parameters that impact the performance associated with the integrated circuit during the voltage ramp transition period; and exiting the dynamic calibration mode responsive to detecting an end of the voltage ramp transition period.

In some implementations, a non-transitory computer-readable medium storing a set of instructions includes one or more instructions that, when executed by one or more processors of an electronic device, cause the electronic device to: detect a start of a voltage ramp transition period associated with changing a voltage at which an integrated circuit operates from a first voltage to a second voltage, wherein changing the voltage from the first voltage to the second voltage causes changes to one or more parameters that impact performance associated with the integrated circuit during the voltage ramp transition period; trigger, responsive to detecting the start of the voltage ramp transition period, a dynamic calibration mode that compensates for the changes to the one or more parameters that impact the performance associated with the integrated circuit during the voltage ramp transition period; and exit the dynamic calibration mode responsive to detecting an end of the voltage ramp transition period.

In some implementations, an apparatus includes means for detecting a start of a voltage ramp transition period associated with changing a voltage at which an integrated circuit operates from a first voltage to a second voltage, wherein changing the voltage from the first voltage to the second voltage causes changes to one or more parameters that impact performance associated with the integrated circuit during the voltage ramp transition period; means for triggering, responsive to detecting the start of the voltage ramp transition period, a dynamic calibration mode that compensates for the changes to the one or more parameters that impact the performance associated with the integrated circuit during the voltage ramp transition period; and means for exiting the dynamic calibration mode responsive to detecting an end of the voltage ramp transition period.

Aspects generally include a method, apparatus, system, computer program product, non-transitory computer-readable medium, user device, user equipment, electronic device, and/or processing system as substantially described with reference to and as illustrated by the drawings and specification.

The foregoing has outlined rather broadly the features and technical advantages of examples according to the disclosure in order that the detailed description that follows may be better understood. Additional features and advantages will be described hereinafter. The conception and specific examples disclosed may be readily utilized as a basis for modifying or designing other structures for carrying out the same purposes of the present disclosure. Such equivalent constructions do not depart from the scope of the appended claims. Characteristics of the concepts disclosed herein, both their organization and method of operation, together with associated advantages will be better understood from the following description when considered in connection with the accompanying figures. Each of the figures is provided for the purposes of illustration and description, and not as a definition of the limits of the claims.

### BRIEF DESCRIPTION OF THE DRAWINGS

So that the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects. The same reference numbers in different drawings may identify the same or similar elements.

FIG. 1 is a diagram illustrating an example electronic device that may support dynamic circuit calibration during voltage change transitions, in accordance with the present disclosure.

FIG. 2 is a diagram illustrating example components included in a memory device that may support dynamic circuit calibration during voltage change transitions, in accordance with the present disclosure.

FIGS. 3A-3B are diagrams illustrating examples associated with dynamic circuit calibration during voltage change transitions, in accordance with the present disclosure.

FIG. 4 is a diagram illustrating a flowchart of an example process associated with dynamic circuit calibration during voltage change transitions, in accordance with the present disclosure.

FIG. 5 is a diagram illustrating an example system that may support dynamic circuit calibration during voltage change transitions, in accordance with the present disclosure.

### DETAILED DESCRIPTION

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. One skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

Dynamic voltage and frequency scaling or dynamic voltage and frequency switching (DVFS) is a power management technique that may be used in a processor or integrated circuit to optimize energy efficiency and performance. In particular, DVFS (interchangeably referred to as dynamic clock and voltage scaling or dynamic clock and voltage switching (DCVS)) is used to dynamically adjust the voltage and clock frequency associated with a processor, an integrated circuit, or another suitable component in accordance with a workload, thermal conditions, or other factors, where the voltage impacts power consumption and the clock frequency impacts performance. For example, when an electronic device is idle, under a light load, or a temperature satisfies (e.g., equals or exceeds) a threshold, DVFS can be used to reduce the voltage and the frequency at which one or more circuits are operated to save power or to cool down the device. Similarly, during periods of high computational demand or other suitable conditions, DVFS can be used to increase the voltage and the frequency at which one or more circuits are operated to improve performance.

Although DVFS techniques enable electronic devices to balance performance and energy efficiency by dynamically adjusting the voltage and frequency at which one or more circuits operate in accordance with workload and/or thermal conditions, DVFS techniques are associated with various challenges. For example, when DVFS is used to increase or decrease the voltage and frequency at which an integrated circuit is operated, there is typically a voltage ramp transition period during which the voltage is gradually changed from a first voltage level to a second voltage level. During the voltage ramp transition period, one or more operating parameters and/or system parameters may change for the circuit(s) associated with the changing voltage and frequency. For example, the changing voltage during the voltage ramp transition period produces or causes changes to one or more operating parameters and/or system parameters, such as one or more delays (e.g., a clock path delay and/or a data path delay), impedances, reference voltages, data eye widths, and/or data eye heights, among other examples. The parameter variations that occur during voltage ramp transition periods are typically acceptable only while the circuit(s) associated with the changing voltage and frequency are operating in a low-performance mode (e.g., when longer delays are acceptable). However, in some cases, there may be a need to improve performance during the voltage ramp transition period, which poses challenges because the frequency at which the circuit(s) operate cannot be increased or decreased until after the voltage has been ramped up or ramped down to the target voltage level.

Various aspects relate generally to dynamic circuit calibration during voltage change transitions. In some aspects, as described herein, a voltage change transition may occur when DVFS techniques are applied to gradually decrease a voltage level from a first (e.g., current) voltage level to a second (e.g., target) voltage level (e.g., to save power during low-performance modes or to mitigate thermal conditions) and/or when DVFS techniques are applied to gradually increase the voltage level from a first (e.g., current) voltage level to a second (e.g., target) voltage level (e.g., to improve performance). Accordingly, in some aspects, an electronic device that employs DVFS techniques may include a calibration controller that may compensate for changes to one or more parameters that impact the performance of an integrated circuit during a voltage ramp transition period. For example, in some aspects, the calibration controller may detect a start of a voltage ramp transition period, and may apply one or more techniques to adjust the one or more parameters that impact the performance of the integrated circuit to return the one or more parameters to an optimal state during the voltage ramp transition period. For example, when the voltage supplied to an integrated circuit changes, the calibration controller may dynamically adjust one or more input/output (I/O) driver and/or I/O receiver codes to compensate for an impedance change as a function of the changing voltage. Additionally, or alternatively, the calibration controller may dynamically compensate one or more delays, reference voltages, data eye widths, data eye heights, and/or other suitable parameters as a function of the changing voltage to improve performance during the voltage ramp transition period. Additionally, or alternatively, the calibration controller may store or access a lookup table (LUT) that includes pre-calibrated values for one or more parameters, which may be retrieved and used to dynamically compensate for one or more parameters. For example, in some aspects, the calibration controller may monitor one or more parameters of the integrated circuit that is subject to the voltage ramp transition period, where a value of the monitored parameter(s) may indicate a current state of the voltage ramp transition period based on a comparison to the entries in the LUT table. In this way, the calibration controller may determine the current voltage, and may retrieve or otherwise obtain the appropriate pre-calibrated values to be used to compensate for the one or more parameters that are changing as a function of the changing voltage (e.g., without having to run a dynamic calibration in a mission mode, which may cause degraded user experience or other adverse effects).

Particular aspects of the subject matter described in this disclosure can be implemented to realize one or more of the following potential advantages. In some examples, by implementing a dynamic calibration mode that compensates for the changes to the one or more parameters that impact the performance associated with an integrated circuit during a voltage ramp transition period, performance of the integrated circuit may be improved prior to a time when the frequency of the integrated circuit can be increased or decreased to a target level that corresponds to the target voltage level of the voltage ramp transition period. In this way, the calibration controller may avoid or reduce a performance and/or power impact that may otherwise occur when one or more parameters associated with the integrated circuit are changing during the voltage ramp transition period from the current voltage level to the target voltage level.

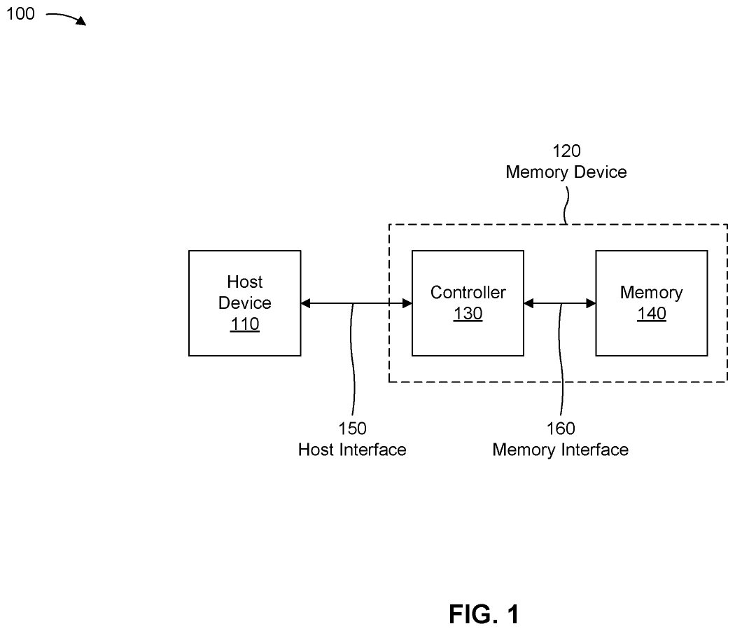

FIG. 1 is a diagram illustrating an example electronic device 100 that may support dynamic circuit calibration during voltage change transitions, in accordance with the present disclosure. The electronic device 100 may include one or more devices, apparatuses, and/or components for performing operations described herein. For example, the electronic device 100 may include a host device 110 and a memory device 120. The memory device 120 may include a controller 130 and memory 140. The host device 110 may communicate with the memory device 120 (e.g., the controller 130 of the memory device 120) via a host interface 150. The controller 130 and the memory 140 may communicate via a memory interface 160.

The electronic device 100 may be any suitable electronic device configured to store data in memory. For example, the electronic device 100 may be a computer, a mobile phone, a wired or wireless communication device, a network device, a server, a device in a data center, a device in a cloud computing environment, a vehicle (e.g., an automobile or an airplane), and/or an Internet of Things (IoT) device. The host device 110 may include one or more processors configured to execute instructions and store data in the memory 140. For example, the host device 110 may include a central processing unit (CPU), a graphics processing unit (GPU), a field-programmable gate array (FPGA), an application-specific integrated circuit (ASIC), or the like.

The memory device 120 may be any electronic device configured to store data in memory. In some aspects, the memory device 120 may be an electronic device configured to store data temporarily in volatile memory. For example, the memory device 120 may be a random-access memory (RAM) device, such as a dynamic RAM (DRAM) device or a static RAM (SRAM) device. In this case, the memory 140 may include volatile memory that requires power to maintain stored data and that loses stored data after the memory device 120 is powered off. For example, the memory 140 may include one or more latches and/or RAM, such as DRAM and/or SRAM. In some aspects, the memory 140 may include non-volatile memory configured to maintain stored data after the memory device 120 is powered off, such as NAND memory or NOR memory. For example, the non-volatile memory may store persistent firmware or other instructions for execution by the controller 130.

The controller 130 may be any device configured to communicate with the host device 110 (e.g., via the host interface 150) and the memory 140 (e.g., via the memory interface 160). Additionally, or alternatively, the controller 130 may be configured to control operations of the memory device 120 and/or the memory 140. For example, the controller 130 may include control logic, a memory controller, a system controller, an ASIC, an FPGA, a processor, a microcontroller, and/or one or more processing components. In some implementations, the controller 130 may be a high-level controller, which may communicate directly with the host device 110 and may instruct one or more low-level controllers regarding memory operations to be performed in connection with the memory 140. In some implementations, the controller 130 may be a low-level controller, which may receive instructions regarding memory operations from a high-level controller that interfaces directly with the host device 110. As an example, a high-level controller may be a solid state drive (SSD) controller, and a low-level controller may be a non-volatile memory controller (e.g., a NAND controller) or a volatile memory controller (e.g., a DRAM controller). In some aspects, a set of operations described herein as being performed by the controller 130 may be performed by a single controller (e.g., the entire set of operations may be performed by a single high-level or low-level controller). Alternatively, a set of operations described herein as being performed by the controller 130 may be performed by more than one controller (e.g., a first subset of the operations may be performed by a high-level controller and a second subset of the operations may be performed by a low-level controller).

The host interface 150 enables communication between the host device 110 and the memory device 120. The host interface 150 may include, for example, a Small Computer System Interface (SCSI), a Serial-Attached SCSI (SAS), a Serial Advanced Technology Attachment (SATA) interface, a Peripheral Component Interconnect Express (PCIe) interface, a Non-Volatile Memory Express (NVMe) interface, a universal serial bus (USB) interface, a Universal Flash Storage (UFS) interface, and/or an embedded multimedia card (eMMC) interface.

The memory interface 160 enables communication between the controller 130 and the memory 140. The memory interface 160 may include a non-volatile memory interface (e.g., for communicating with non-volatile memory), such as a NAND interface or a NOR interface. Additionally, or alternatively, the memory interface 160 may include a volatile memory interface (e.g., for communicating with volatile memory), such as a double data rate (DDR) interface.

In some aspects, as described in more detail elsewhere herein, one or more systems, devices, apparatuses, components, and/or controllers of FIG. 1 may be configured to detect a start of a voltage ramp transition period associated with changing a voltage at which an integrated circuit operates from a first voltage to a second voltage, wherein changing the voltage from the first voltage to the second voltage causes changes to one or more parameters that impact performance associated with the integrated circuit during the voltage ramp transition period; trigger, responsive to detecting the start of the voltage ramp transition period, a dynamic calibration mode that compensates for the changes to the one or more parameters that impact the performance associated with the integrated circuit during the voltage ramp transition period; and exit the dynamic calibration mode responsive to detecting an end of the voltage ramp transition period. Additionally, or alternatively, one or more systems, devices, apparatuses, components, and/or controllers of FIG. 1 may be configured to perform one or more other operations described herein.

As indicated above, FIG. 1 is provided as an example. Other examples may differ from what is described with regard to FIG. 1. For example, some aspects described herein are broadly applicable to other circuits, including circuits that are fully contained on-die (e.g., within a system-on-chip (SoC)) and/or circuits associated with non-memory external interfaces (e.g., a serializer/deserializer (SerDes)).

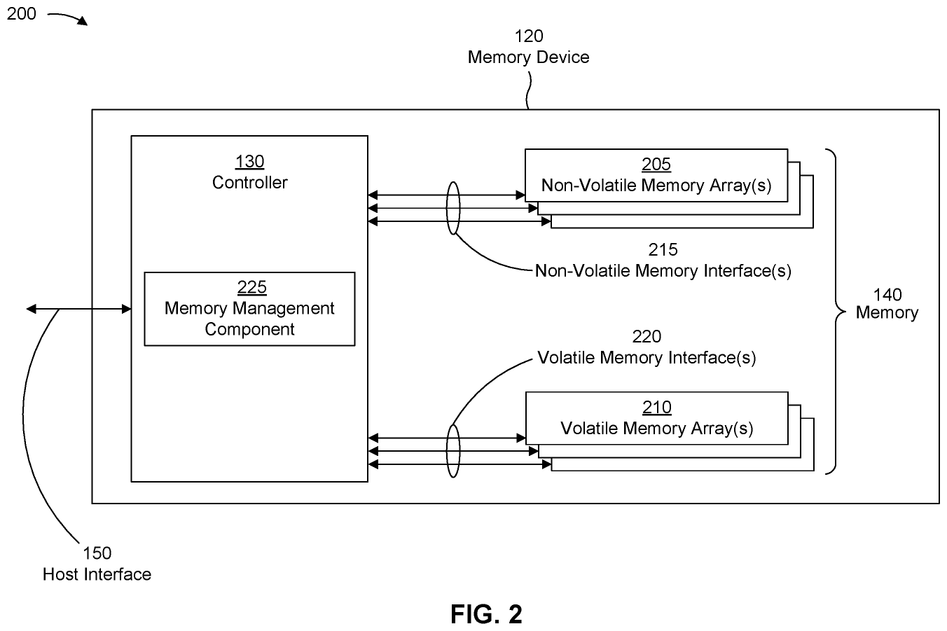

FIG. 2 is a diagram illustrating an example 200 of components included in a memory device 120 that may support dynamic circuit calibration during voltage change transitions, in accordance with the present disclosure. As described above in connection with FIG. 1, the memory device 120 may include a controller 130 and memory 140. As shown in FIG. 2, the memory 140 may include one or more non-volatile memory arrays 205, such as one or more NAND memory arrays and/or one or more NOR memory arrays. Additionally, or alternatively, the memory 140 may include one or more volatile memory arrays 210, such as one or more SRAM arrays and/or one or more DRAM arrays. The controller 130 may transmit signals to and receive signals from a non-volatile memory array 205 using a non-volatile memory interface 215. The controller 130 may transmit signals to and receive signals from a volatile memory array 210 using a volatile memory interface 220.

The controller 130 may control operations of the memory 140, such as by executing one or more instructions. For example, the memory device 120 may store one or more instructions in the memory 140 as firmware, and the controller 130 may execute the one or more instructions stored in the memory 140. Additionally, or alternatively, the controller 130 may receive one or more instructions from the host device 110 via the host interface 150, and may execute those one or more instructions. In some implementations, a non-transitory computer-readable medium (e.g., volatile memory and/or non-volatile memory) may store a set of instructions (e.g., one or more instructions or code) for execution by the controller 130. The controller 130 may execute the set of instructions to perform one or more operations or methods described herein. In some aspects, execution of the set of instructions, by the controller 130, causes the controller 130 and/or the memory device 120 to perform one or more operations or methods described herein. In some implementations, hardwired circuitry is used instead of or in combination with the one or more instructions to perform one or more operations or methods described herein. Additionally, or alternatively, the controller 130 and/or one or more components of the memory device 120 may be configured to perform one or more operations or methods described herein. An instruction is sometimes called a “command.”

For example, the controller 130 may transmit signals to and/or receive signals from the memory 140 based on the one or more instructions, such as to transfer data to (e.g., write or program), to transfer data from (e.g., read), and/or to erase all or a portion of the memory 140 (e.g., one or more memory cells, pages, sub-blocks, blocks, or planes of the memory 140). Additionally, or alternatively, the controller 130 may be configured to control access to the memory 140 and/or to provide a translation layer between the host device 110 and the memory 140 (e.g., for mapping logical addresses to physical addresses of a memory array). In some implementations, the controller 130 may translate a host interface command (e.g., a command received from the host device 110) into a memory interface command (e.g., a command for performing an operation on a memory array).

As shown in FIG. 2, the controller 130 may include a memory management component 225. In some implementations, one or more of these components are implemented as one or more instructions (e.g., firmware) executed by the controller 130. Alternatively, one or more of these components may be implemented as dedicated integrated circuits distinct from the controller 130.

The memory management component 225 may be configured to manage performance of the memory device 120. For example, the memory management component 225 may perform wear leveling, bad block management, block retirement, read disturb management, and/or other memory management operations. In some implementations, the memory device 120 may store (e.g., in memory 140) one or more memory management tables. A memory management table may store information that may be used by or updated by the memory management component 225, such as information regarding memory block age, memory block erase count, and/or error information associated with a memory partition (e.g., a memory cell, a row of memory, a block of memory, or the like). Additionally, or alternatively, the memory management component 225 may employ DVFS or DCVS techniques to decrease a voltage level at which a circuit operates (e.g., to save power during low-performance modes) and/or to increase the voltage level at which a circuit operates (e.g., during a high-performance mode or after exiting from a low-performance mode).

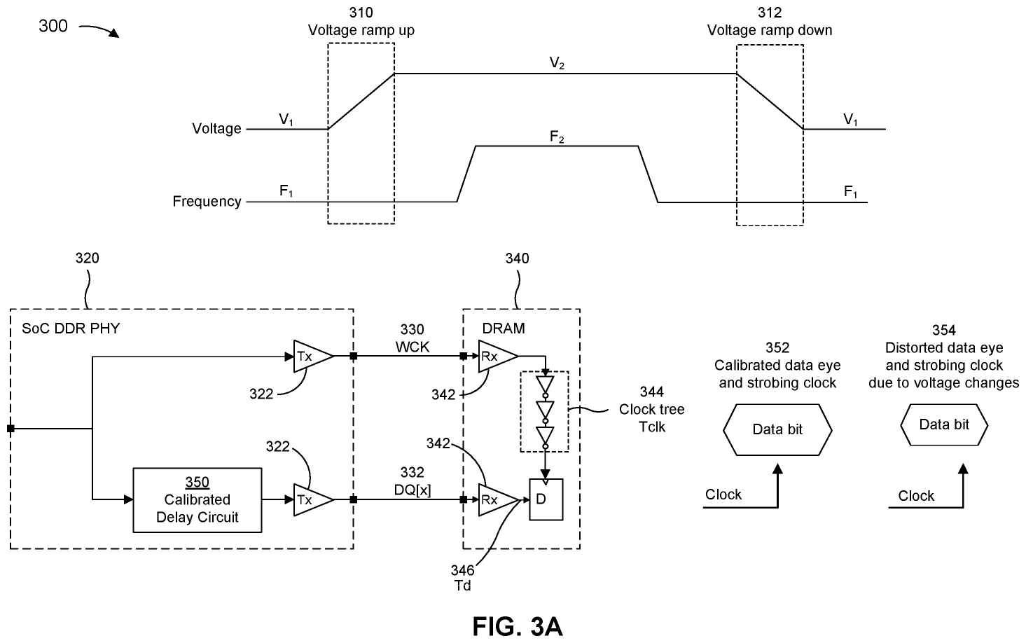

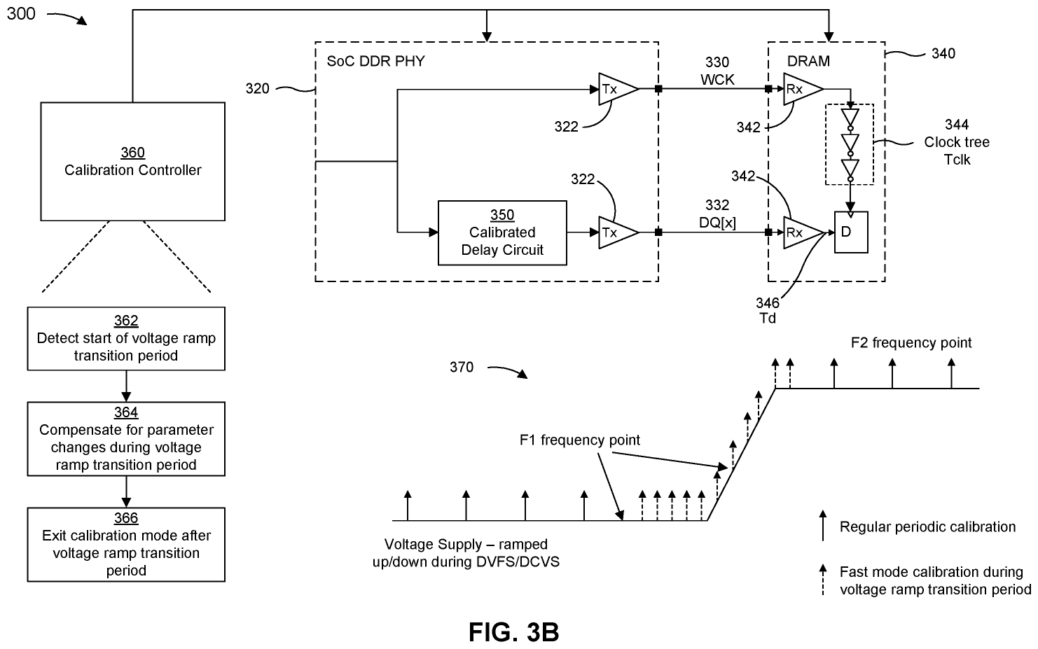

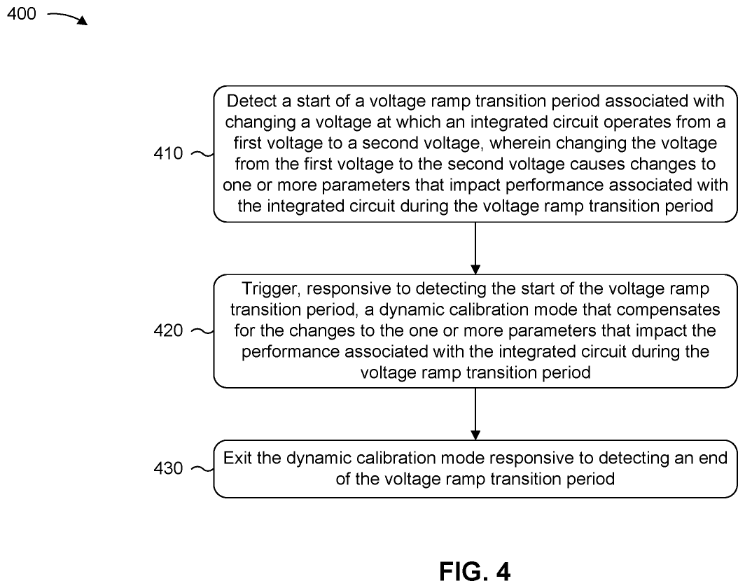

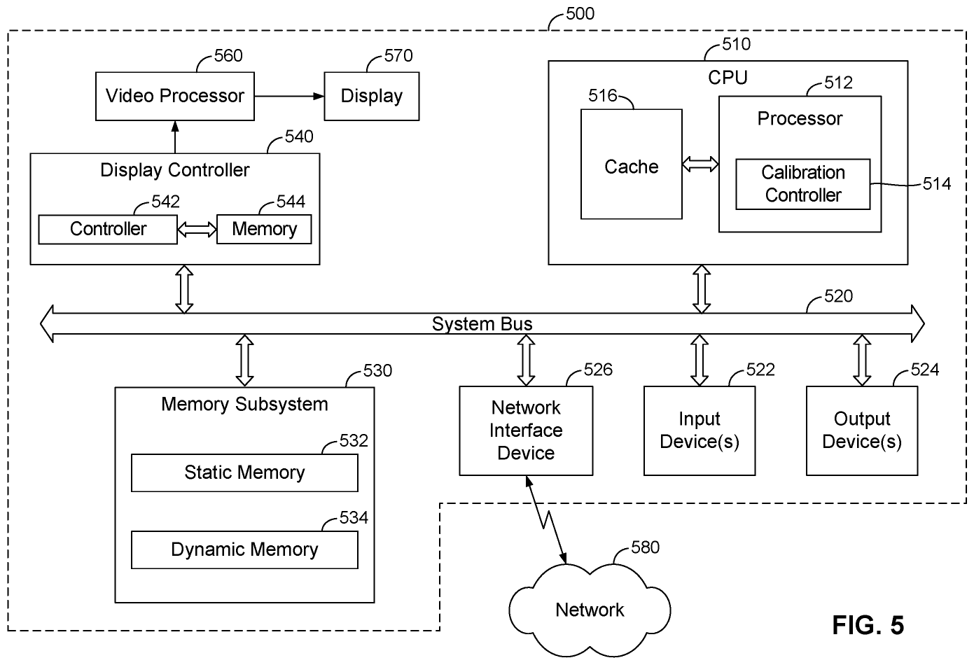

One or more devices or components shown in FIG. 2 may be configured to perform operations described herein, such as one or more operations and/or methods described in connection with FIGS. 3A-3B, FIG. 4, and/or FIG. 5. For example, the controller 130, the memory management component 225, may be configured to perform one or more operations and/or methods for the memory device 120.

For example, in some aspects, the memory device 120 may include means for detecting a start of a voltage ramp transition period associated with changing a voltage at which an integrated circuit operates from a first voltage to a second voltage, wherein changing the voltage from the first voltage to the second voltage causes changes to one or more parameters that impact performance associated with the integrated circuit during the voltage ramp transition period; means for triggering, responsive to detecting the start of the voltage ramp transition period, a dynamic calibration mode that compensates for the changes to the one or more parameters that impact the performance associated with the integrated circuit during the voltage ramp transition period; and/or means for exiting the dynamic calibration mode responsive to detecting an end of the voltage ramp transition period. In some aspects, the means for the memory device 120 to perform processes and/or operations described herein may include one or more components shown in FIG. 2, such as controller 130 and/or memory management component 225, among other examples.

The number and arrangement of components shown in FIG. 2 are provided as an example. In practice, there may be additional components, fewer components, different components, or differently arranged components than those shown in FIG. 2. Furthermore, two or more components shown in FIG. 2 may be implemented within a single component, or a single component shown in FIG. 2 may be implemented as multiple, distributed components. Additionally, or alternatively, a set of components (e.g., one or more components) shown in FIG. 2 may perform one or more operations described as being performed by another set of components shown in FIG. 2.

FIGS. 3A-3B are diagrams illustrating examples 300 associated with dynamic circuit calibration during voltage change transitions, in accordance with the present disclosure. More particularly, as described herein, DVFS (alternatively DCVS) is a power management technique that may be used in a processor or integrated circuit to optimize energy efficiency and performance. In particular, DVFS is used to dynamically adjust the voltage and clock frequency associated with a processor, an integrated circuit, or another suitable component in accordance with a workload, thermal conditions, or other factors, where the voltage impacts power consumption and the clock frequency impacts performance. For example, DVFS can be used to reduce the voltage and/or the frequency at which one or more circuits are operated to save power or to cool down an electronic device and/or to increase the voltage and/or the frequency at which one or more circuits are operated to improve performance.

Although DVFS techniques enable electronic devices to balance performance and energy efficiency by dynamically adjusting the voltage and frequency at which one or more circuits operate in accordance with workload and/or thermal conditions, DVFS techniques are associated with various challenges. For example, when DVFS is used to increase or decrease the voltage and frequency at which an integrated circuit is operated, there is typically a voltage ramp transition period during which the voltage is gradually changed from a first voltage level to a second voltage level. For example, as shown by reference number 310 in FIG. 3A, DVFS techniques may be applied to gradually increase the voltage level at which an integrated circuit operates from a first voltage level (shown as V₁) to a second voltage level (shown as V₂). Prior to the voltage ramp transition period in which the voltage level is gradually ramped up, the circuit that is controlled using the DVFS techniques may be operated at a first frequency (shown as F₁), and the circuit may continue to operate at the first frequency during the voltage ramp transition period. For example, as shown, the circuit may continue to operate at the first frequency during the voltage ramp transition period and may later be increased to a second (higher) frequency associated with improved performance after the voltage level has been ramped up to the second voltage level. Furthermore, as shown by reference number 312 in FIG. 3A, DVFS techniques may be similarly applied to gradually decrease the voltage level at which the integrated circuit operates (e.g., from V₁ to V₂). In this case, prior to the voltage ramp transition period in which the voltage level is gradually ramped down, the frequency of the circuit may be reduced to the lower frequency associated with the target voltage level (e.g., from F₁ to F₂), thus causing a performance impact.

During the voltage ramp transition period, the voltage changes impact changes in one or more circuit parameters and/or system parameters, such as one or more delays (e.g., a clock path delay and/or a data path delay), impedances, reference voltages, data eye widths, and/or data eye heights, among other examples. The parameter variations that occur during voltage ramp transition periods are typically acceptable only while the circuit(s) associated with the changing voltage and frequency are operating in a low-performance mode (e.g., when a lower frequency is acceptable). For example, FIGS. 3A-3B illustrate an example of a DDR circuit that may experience substantial variation in one or more delays, impedances, reference voltages, data eye widths, data eye heights, and/or other parameters or characteristics that may impact performance during a voltage ramp transition period (e.g., while DDR data traffic is ongoing). However, the DDR circuit is provided only as an example of a circuit that may experience changes in parameters during a voltage ramp transition period, and some aspects described herein may be generally applicable to any suitable circuit that may experience changes in one or more parameters that impact performance during a voltage ramp transition period.

As shown in FIGS. 3A-3B, the DDR circuit may include a system on chip (SoC) component 320 corresponding to a DDR PHY component (e.g., a physical layer interface circuit), where the SoC component 320 may include a set of I/O drivers (or I/O transmitters (Tx)) 322. In some aspects, when the SoC component 320 is interfacing with a memory device, such as a DRAM device, the DDR PHY component may be included in the controller of the memory device (e.g., controller 130 in FIG. 1 and/or FIG. 2). As further shown in FIGS. 3A-3B, the I/O drivers 322 may pass one or more signals, such as a write clock signal 330, shown as WCK, and data signals 332, shown as DQ[x], to a DRAM device 340 that interfaces with the SoC component 320 (e.g., in a package or on a board that houses the SoC component 320 and the DRAM device 340).

Furthermore, it will be appreciated that the relationship between the WCK-DQ (or clock-data) signals is only one example (e.g., an analogous example may be a CK-CA relationship for a clock strobing/latching a command-address (CA) bus of the memory device). As further shown in FIGS. 3A-3B, the DRAM device 340 may include a set of I/O receivers (Rx) 342 that receive the signals provided by the I/O drivers 322 of the SoC component 320. For example, as shown, the DRAM device 340 includes a first I/O receiver 342 that receives the write clock signal 330 and a second I/O receiver that receives the data strobe signal 332. In some aspects, the first I/O receiver 342 may provide the write clock signal 330 to a latch or register (D) via a clock tree 344 associated with a clock path delay, Tclk (e.g., to temporarily latch a bit for a cycle before passing the bit to an internal structure of the memory device). As shown by reference number 346, the second I/O receiver 342 may provide the data strobe signal 332 to the latch/register D via a data path associated with a data path delay, Td.

In general, the DRAM clock path delay, Tclk, and the DRAM data path delay, Td, are imbalanced due to architectural considerations. The calibrated delay circuit 350 of the SoC component 320 compensates for the {Tclk−Td} imbalance and an additional T/4 (quarter cycle) offset to position the strobing clock in the middle of the data bit. For example, in a DRAM device, the clock path delay, Tclk, and the data path delay, Td, are imbalanced because the DRAM clock distribution to all bits needs both buffering and routing (e.g., the clock path delay is long), while each DQ data bit has a latched receiver that is close to the data input, making the data path delay very short (e.g., relative to the clock path delay). Accordingly, the SoC component 320 may be configured to compensate for the imbalance of the offset {Tclk−Td} in the DRAM device, and to position a strobing clock in the middle of a data eye. For example, in some aspects, the SoC component 320 may include a calibrated delay circuit 350 that may provide a fixed delay, based on a closed-loop hardware-based and/or software-based calibration process. For example, as shown by reference number 352 in FIG. 3A, the calibrated delay circuit 350 may be calibrated to compensate for the offset (or delay delta) {Tclk−Td} that is otherwise fixed in the DRAM device. In particular, as shown by reference number 352, the calibrated delay circuit 350 is calibrated to compensate for the offset {Tclk−Td} outside voltage ramp transition periods such that the strobing clock is provided in the middle of the data bit. However, when the voltage supplied to the DRAM device 340 is changing (e.g., increasing or decreasing) from a first voltage level to a second voltage level during a voltage ramp transition period, the changing voltage causes changes to the delay associated with the clock path and the delay associated with the data path. As a result, the voltage-induced changes to the clock-data relationship {Tclk−Td} at the inputs of the latch D may produce a timing failure. For example, as shown by reference number 354, the changing voltage and the associated changes to the delay difference that occur during a voltage ramp transition period result in the strobing clock moving away from the center of the data bit (e.g., towards the right end in the depicted example, potentially to the point of violating a setup time or hold time constraints of the latch/register D). In addition, as further shown by reference number 352, the changing voltage during the voltage ramp transition period causes distortion to the data eye, which is compressed and therefore associated with worse performance relative to the calibrated data eye (e.g., due to duty cycle distortion).

Accordingly, one approach to address the degraded performance that may occur during a voltage ramp transition period is to absorb the timing impact or other performance impact that is caused by the parameter changes that occur during the voltage ramp transition period. For example, one potential approach is to absorb the timing impact associated with the change to {Tclk−Td} in a system budget associated with the DRAM device 340, where {Tclk−Td} represents the difference between the delays associated with the clock path delay, Tclk, and the delay associated with the data path, Td. For example, during a voltage ramp transition period in which a voltage level is increasing or decreasing from a first voltage level to a second voltage level, the SoC component 320 and/or DRAM device 340 may operate at a lower frequency to absorb the timing impact associated with the change to {Tclk−Td} that occurs during a voltage ramp transition period. However, this approach leads to degraded performance during the voltage ramp transition period.

Accordingly, some aspects described herein relate to dynamic circuit calibration techniques that may be applied during a voltage ramp transition period. For example, as described herein and shown in FIG. 3B, an electronic device that employs DVFS techniques may include a calibration controller 360 that may compensate for changes to one or more parameters that impact the performance of an integrated circuit during a voltage ramp transition period. For example, as shown in FIG. 3B, the calibration controller 360 may be coupled to the SoC component 320 to allow for control of the calibrated delay circuit 350, the Tx elements 322, and/or any other component or device of the SoC component 320. Additionally, or alternatively, the calibration controller 360 may be coupled to the DRAM device 340 to allow for control of the Rx elements 342, the clock tree 344, and/or any other component or device of the DRAM device 340. In some aspects, the calibration controller 360 may be implemented in hardware, software, firmware, or any suitable combination thereof.

Furthermore, in some aspects, the calibration controller 360 may be an individual controller, or multiple controllers that are used to calibrate or otherwise control one or more passive circuits during a voltage ramp transition period. For example, the calibration controller 360 may detect a start of a voltage ramp transition period, and may apply one or more techniques to adjust the one or more parameters that impact the performance of the integrated circuit to return the one or more parameters to an optimal state (e.g., similar or close to conditions where a strobing clock is provided at the center of a calibrated data eye) during the voltage ramp transition period. For example, when the voltage supplied to the integrated circuit changes, the calibration controller 360 may dynamically adjust one or more I/O driver codes to compensate for an impedance change as a function of the changing voltage. Additionally, or alternatively, the calibration controller 360 may dynamically adjust one or more parameters of the I/O receivers 342, such as an input-referred (or Vref) offset. Additionally, or alternatively, the calibration circuit may dynamically compensate one or more parameters, such as delays, reference voltages, data eye widths, data eye heights, and/or other suitable parameters as a function of the changing voltage during the voltage ramp transition period to improve performance during the voltage ramp transition period.

For example, as shown in FIG. 3B, at block 362, the calibration controller 360 may detect the start of a voltage ramp transition period in which DVFS techniques are applied to change the operating voltage of an integrated circuit (e.g., the DRAM device 340) from a first voltage to a second voltage, which causes changes to one or more parameters that impact the performance associated with the integrated circuit during the voltage ramp transition period. For example, during the voltage ramp transition period, one or more delays, impedances, reference voltages, data eye widths, and/or other parameters may change, whereby the calibration controller 360 may detect the start of a voltage ramp transition period to determine whether and/or when to trigger a dynamic calibration mode. For example, prior to, after, or between voltage ramp transition periods, the calibration controller 360 may periodically calibrate one or more delays, impedances, reference voltages, data eye widths, data eye heights, and/or other parameters that impact the performance of the integrated circuit based on the constant or relatively stable voltage at which the integrated circuit operates outside a voltage ramp transition period. However, during voltage ramp transition periods, the calibration controller 360 may need to calibrate (e.g., compensate for) changes to one or more delays, impedances, reference voltages, data eye widths, and/or other parameters that impact the performance of the integrated circuit as a function of the changing voltage.

Accordingly, as shown by block 362, the calibration controller 360 may detect the start of a voltage ramp transition period to determine whether and/or when to initiate the dynamic calibration mode in which one or more delays, impedances, reference voltages, data eye widths, data eye heights, and/or other parameters that impact the performance of the integrated circuit are dynamically calibrated to compensate for the changing voltage during the voltage ramp transition period. For example, in some aspects, the calibration controller 360 may include or may be coupled to a voltage sensor that measures the voltage supplied to the DRAM device 340 (or other integrated circuit) subject to dynamic calibration. Additionally, or alternatively, the DRAM device 340 or the SoC component 320 may obtain a local circuit measurement that indicates the voltage supplied to the DRAM device 340 (or other integrated circuit(s)) subject to dynamic calibration. In such cases, the voltage sensor or local circuit measurement may provide, to the calibration controller 360, a signal or other suitable information that indicates the voltage supplied to the DRAM device 340 (e.g., from a circuit or device involved in the DVFS orchestration), which the calibration controller 360 can then use to detect the start of a voltage ramp transition period (e.g., based on an increase or a decrease in the operating voltage). Additionally, or alternatively, a module or component that controls a power management integrated circuit (PMIC) used to set the operating voltage of the integrated circuit may generate a signal to indicate when a voltage ramp transition period has started or ended, which the calibration controller 360 can use to detect the start of a voltage ramp transition period. Additionally, or alternatively, the SoC (DDR PHY) component 320 and a circuit controlling the DVFS (e.g., including the PMIC) may be synchronized at an SoC level, whereby the SoC component 320 and the circuit controlling the DVFS may exchange synchronization messages that convey to the SoC component 320 and the associated calibration controller 360, the timing of the start and the end of the voltage ramp transition period.

As further shown in FIG. 3B, at block 364, the calibration controller 360 may dynamically compensate for one or more parameter changes that impact the performance of the integrated circuit during the voltage ramp transition period. In particular, during the voltage ramp transition period, the calibration controller 360 may dynamically compensate for changes to one or more delays, impedances, reference voltages, data eye widths, data eye heights, and/or other parameters associated with the integrated circuit as a function of the changing voltage during the voltage ramp transition period. For example, with reference to the example circuit shown in FIGS. 3A-3B, the I/O drivers 322 associated with the SoC component 320 have to be calibrated to a precise impedance for the interface between the SoC component 320 and the DRAM device 340 to operate at a high speed with suitable signal integrity.

However, when there is a change in I/O power supply voltage during a voltage ramp transition period, the impedance of the I/O drivers 322 changes, which leads to degraded signal integrity and potential system failures. Furthermore, similar issues may apply to the I/O receivers 342 in the DRAM device 340 when the I/O power supply changes due to a change in voltage during a voltage ramp transition period.

Accordingly, in one example of dynamically compensating for parameter changes that occur during a voltage ramp transition period, the calibration controller 360 may dynamically change or adjust the impedances associated with the I/O drivers 322 and/or may dynamically change or adjust a Vref offset or other parameters of the I/O receivers 342 as a function of the changing voltage during a voltage ramp transition period. For example, in some aspects, the calibration controller 360 may trigger a fast I/O calibration mode that is active only during the voltage ramp transition period, and may increment or decrement one or more I/O codes associated with the I/O drivers 322 and/or I/O receivers 342 multiple times during the time period in which the voltage is transitioned (e.g., from V₁ to V₂). For example, the I/O codes may be incremented or decremented as a function of the changing voltage to constrain a maximum deviation of the impedance of the I/O drivers 322 and/or the Vref offset of the I/O receivers 342 from an optimal value (e.g., associated with a calibrated data eye). Additionally, or alternatively, one or more impedance codes for the I/O drivers 322 may be pre-calibrated for the initial and target voltage (e.g., for V₁ and V₂) and for one or more intermediate voltages between the initial and target voltage, and the pre-calibrated impedance codes may be used to program the I/O drivers 322 at regular intervals during the voltage ramp transition period. For example, in some aspects, the calibration controller 360 may store or access a lookup table (LUT) that includes pre-calibrated values for one or more parameters, which may be retrieved and used to dynamically compensate for one or more parameters during the voltage ramp transition period. For example, in some aspects, the calibration controller 360 may monitor one or more parameters of the integrated circuit that is subject to the voltage ramp transition period, where a value of the monitored parameter(s) may indicate a current state of the voltage ramp transition period based on a comparison to the entries in the LUT table. In this way, the calibration controller 360 may determine the current voltage, and may retrieve or otherwise obtain the appropriate pre-calibrated values to be used to compensate for the one or more parameters that are changing as a function of the changing voltage (e.g., without having to run a dynamic calibration in a mission mode, which may cause degraded user experience or other adverse effects).

Accordingly, as described herein, the calibration controller 360 may generally employ one or more techniques to calibrate one or more parameters that impact the performance of an integrated circuit during a voltage ramp transition period in order to maintain the parameters as close to an optimal state as possible (e.g., such that a strobing clock signal is provided at the center of a data bit that has a calibrated data eye width). For example, some aspects described herein relate to example calibration techniques that may be applied to dynamically calibrate one or more impedances during the voltage ramp transition period, and the calibration controller 360 may also apply one or more suitable techniques to dynamically calibrate other parameters that change as a function of the changing voltage during a voltage ramp transition period (e.g., one or more delays, reference voltages, data eye widths, and/or data eye heights, among other examples). For example, when the dynamic calibration mode is triggered (e.g., responsive to detecting the start of the voltage ramp transition period), the calibration controller 360 may receive, obtain, or otherwise determine the voltage at which the integrated circuit is operating at various time instances (e.g., based on a signal from a voltage sensor, a local circuit measurement, a signal from a PMIC controller, a voltage scaling table, or the like), and the calibration controller 360 may initiate one or more new or updated settings for the one or more parameters that are calibrated as a function of the voltage at each time instance. For example, the calibration controller 360 may check the current voltage at which the integrated circuit is operating at periodic intervals and may initiate the one or more new or updated settings at each time interval. Additionally, or alternatively, the calibration controller 360 may initiate one or more new or updated settings when a delta between the current voltage and a most recent settings update satisfies a threshold.

As further shown in FIG. 3B, at block 366, the calibration controller 360 may exit the dynamic calibration mode responsive to detecting an end of the voltage ramp transition period (e.g., indicating that the voltage has been ramped up or ramped down to the target level). For example, as described in more detail elsewhere herein, the calibration controller 360 may detect the end of the voltage ramp transition period in accordance with a signal provided by a voltage sensor that measures and/or indicates the current voltage, a local circuit measurement that indicates the current voltage, a signal from a module or component that controls a PMIC used to set the operating voltage, and/or based on a synchronization between the calibration controller 360 and other SoC or PMIC components configured to manage or coordinate DVFS transitions. For example, as shown by reference number 370 in FIG. 3B, the calibration circuit may perform regular calibration at periodic intervals outside of time periods in which voltage is being gradually increased or decreased (e.g., shown by solid vertical arrows). Furthermore, when the calibration controller 360 detects the start of a voltage ramp transition period (e.g., an increase in the operating voltage in the example depicted in FIG. 3B), the calibration controller 360 may trigger a dynamic calibration mode in which one or more parameters of the integrated circuit are calibrated (e.g., adjusted) as a function of the changing voltage during the voltage ramp transition period. For example, in FIG. 3B, the fast calibration mode during voltage ramp transition periods is illustrated by dashed vertical arrows, occurring at more frequent time intervals during the voltage ramp transition period or when a delta between the current voltage and a voltage associated with a previous calibration instance satisfies a threshold, as compared to a regular calibration mode illustrated by solid arrows, occurring at more infrequent time intervals. In some aspects, the calibrations associated with the dynamic calibration mode may occur at periodic intervals, and the dynamic calibrations may occur more often during the voltage ramp transition period relative to time periods when the voltage is constant or stable. Additionally, or alternatively, the dynamic calibration may occur at non-periodic time intervals (e.g., as the transitioning voltage passes through equally spaced voltage points and/or when certain circuit and/or system parameter changes satisfy (e.g., exceed) a threshold. Furthermore, a frequency (e.g., periodicity) of the dynamic calibrations (e.g., updates) may be varied proportionally with the rate of voltage change, such that faster voltage changes may be compensated with faster dynamic calibration updates (and vice versa). Furthermore, as shown in FIG. 3B, the calibration controller 360 may return to the regular periodic calibration (shown by a return to solid vertical arrows) after the voltage ramp transition period has ended. In this way, by implementing the dynamic calibration mode that dynamically compensates for the changes to the one or more parameters that impact the performance associated with the integrated circuit during a voltage ramp transition period, performance of the integrated circuit may be improved prior to a time when the frequency of the integrated circuit can be increased or decreased to a target level that corresponds to the target voltage level of the voltage ramp transition period. In this way, the calibration circuit may avoid or reduce a performance and/or power impact that may otherwise occur when the changing voltage during the voltage ramp transition period causes changes to one or more parameters associated with the integrated circuit during the voltage ramp transition period.

As indicated above, FIGS. 3A-3B are provided as examples. Other examples may differ from what is described with regard to FIGS. 3A-3B.

FIG. 4 is a flowchart of an example process 400 associated with dynamic circuit calibration during voltage change transitions, in accordance with the present disclosure. In some aspects, one or more process blocks of FIG. 4 are performed by a calibration circuit (e.g., calibration controller 360). In some aspects, one or more process blocks of FIG. 4 are performed by another device or a group of devices separate from or including the calibration circuit, such as an electronic device (e.g., electronic device 100, memory device 120, or the like).

As shown in FIG. 4, process 400 may include detecting a start of a voltage ramp transition period associated with changing a voltage at which an integrated circuit operates from a first voltage to a second voltage, wherein changing the voltage from the first voltage to the second voltage causes changes to one or more parameters that impact performance associated with the integrated circuit during the voltage ramp transition period (block 410). For example, the calibration circuit may detect a start of a voltage ramp transition period associated with changing a voltage at which an integrated circuit operates from a first voltage to a second voltage, wherein changing the voltage from the first voltage to the second voltage causes changes to one or more parameters that impact performance associated with the integrated circuit during the voltage ramp transition period, as described above.

As further shown in FIG. 4, process 400 may include triggering, responsive to detecting the start of the voltage ramp transition period, a dynamic calibration mode that compensates for the changes to the one or more parameters that impact the performance associated with the integrated circuit during the voltage ramp transition period (block 420). For example, the calibration circuit may trigger, responsive to detecting the start of the voltage ramp transition period, a dynamic calibration mode that compensates for the changes to the one or more parameters that impact the performance associated with the integrated circuit during the voltage ramp transition period, as described above.

As further shown in FIG. 4, process 400 may include exiting the dynamic calibration mode responsive to detecting an end of the voltage ramp transition period (block 430). For example, the calibration circuit may exit the dynamic calibration mode responsive to detecting an end of the voltage ramp transition period, as described above.

Process 400 may include additional aspects, such as any single aspect or any combination of aspects described below and/or in connection with one or more other processes described elsewhere herein.

In a first aspect, the dynamic calibration mode calibrates one or more impedance codes associated with one or more I/O devices as a function of the voltage at which the integrated circuit operates to compensate for the changes to the one or more parameters that impact the performance associated with the integrated circuit during the voltage ramp transition period.

In a second aspect, alone or in combination with the first aspect, the dynamic calibration mode adjusts values of the one or more impedance codes associated with the one or more I/O devices multiple times during the voltage ramp transition period.

In a third aspect, alone or in combination with one or more of the first and second aspects, the dynamic calibration mode adjusts values of the one or more parameters at periodic intervals during the voltage ramp transition period based on pre-calibrated values associated with one or more of the first voltage, the second voltage, or one or more intermediate voltages between the first voltage and the second voltage.

In a fourth aspect, alone or in combination with one or more of the first through third aspects, the one or more pre-calibrated values are stored in a lookup table.

In a fifth aspect, alone or in combination with one or more of the first through fourth aspects, the start and the end of the voltage ramp transition period are detected according to an indicator provided by a voltage sensor associated with the integrated circuit or a local measurement associated with the integrated circuit.

In a sixth aspect, alone or in combination with one or more of the first through fifth aspects, the start and the end of the voltage ramp transition period are detected according to a signal received from a component that controls a power management integrated circuit.

In a seventh aspect, alone or in combination with one or more of the first through sixth aspects, the start and the end of the voltage ramp transition period are detected according to a signal that relates to switching a frequency at which the integrated circuit operates from a first frequency to a second frequency.

In an eighth aspect, alone or in combination with one or more of the first through seventh aspects, the voltage ramp transition period is associated with increasing the voltage at which the integrated circuit operates from the first voltage to the second voltage.

In a ninth aspect, alone or in combination with one or more of the first through eighth aspects, the voltage ramp transition period is associated with reducing the voltage at which the integrated circuit operates from the first voltage to the second voltage.

In a tenth aspect, alone or in combination with one or more of the first through ninth aspects, the one or more parameters that are compensated as a function of the voltage during the voltage ramp transition period include one or more delays, one or more impedances, one or more reference voltages, a data eye width, or a data eye height.

Although FIG. 4 shows example blocks of process 400, in some aspects, process 400 includes additional blocks, fewer blocks, different blocks, or differently arranged blocks than those depicted in FIG. 4. Additionally, or alternatively, two or more of the blocks of process 400 may be performed in parallel.

FIG. 5 is a diagram illustrating an example system 500 that may support dynamic circuit calibration during voltage change transitions, in accordance with the present disclosure. More particularly, as described herein, the dynamic circuit calibration mechanisms and the corresponding methods or processes described herein can be employed in any circuit, including but not limited to a microprocessor-based circuit, system, or others suitable electronic device. For example, electronic devices that can include or otherwise employ the dynamic circuit calibration mechanisms described herein can comprise, without limitation, mobile phones, cellular phones, computers, portable computers, desktop computers, personal digital assistants (PDAs), monitors, computer monitors, televisions, tuners, radios, satellite radios, digital music players, portable music players, digital video players, digital video disc (DVD) players, portable digital video players, or the like.

For example, in some aspects, FIG. 5 illustrates an example system 500 that can employ the dynamic circuit calibration mechanisms and corresponding methods and/or processes described in further detail herein. For example, as shown in FIG. 5, the system 500 may include a CPU 510 that includes a cache 516 and a processor 512, which may include a calibration controller 514 configured to perform one or more operations described herein in connection with FIGS. 3A-3B. Furthermore, although FIG. 5 illustrates that the calibration controller 514 is included in the processor 512, the calibration controller 514 may reside at any suitable location within the electronic device 500, such as within an integrated circuit that is controlled using DVFS techniques and/or on an external integrated circuit. Additionally, or alternatively, the calibration controller 514 may be configured to perform one or more processes described herein, such as process 400 of FIG. 4. Additionally, or alternatively, one or more components shown in FIG. 5 may be implemented at least in part as software stored in one or more memories. For example, a component (or a portion of a component) may be implemented as instructions or code stored in a non-transitory computer-readable medium and executable by one or more controllers or one or more processors to perform the functions or operations of the component.

For example, in some aspects, the calibration controller 514 may be configured to detect a start of a voltage ramp transition period associated with changing a voltage at which an integrated circuit operates from a first voltage to a second voltage, wherein changing the voltage from the first voltage to the second voltage causes changes to one or more parameters that impact performance associated with the integrated circuit during the voltage ramp transition period; trigger, responsive to detecting the start of the voltage ramp transition period, a dynamic calibration mode that compensates for the changes to the one or more parameters that impact the performance associated with the integrated circuit during the voltage ramp transition period; and exit the dynamic calibration mode responsive to detecting an end of the voltage ramp transition period.

In some aspects, the CPU 510 may be coupled to a system bus 520, which may intercouple various other devices or components included in the system 500. The CPU 510 may exchange address, control, and data information over the system bus 520 to communicate with the other devices or components included in the system 500. For example, as illustrated in FIG. 5, the devices or components included in the system 500 can include a memory subsystem 530 that can include static memory 532 and/or dynamic memory 534, one or more input devices 522, one or more output devices 524, a network interface device 526, and a display controller 540. In various embodiments, the input devices 522 can include any suitable input device type, such as input keys, switches, voice processors, or the like. The output devices 524 can similarly include any suitable output device type, such as audio, video, other visual indicators, or the like. The network interface device 526 can be any device configured to allow exchange of data to and from a network 580, which may comprise any suitable network type, including but not limited to a wired or wireless network, private or public network, a local area network (LAN), a wide local area network (WLAN), and the Internet. The network interface device 526 can support any type of communication protocol desired. The CPU 510 can access the memory subsystem 530 over the system bus 520.

In some aspects, the CPU 510 can also access the display controller 540 over the system bus 520 to control information sent to a display 570. The display controller 540 can include a memory controller 542 and memory 544 to store data to be sent to the display 570 in response to communications with the CPU 510. The display controller 540 sends information to the display 570 to be displayed via a video processor 560, which processes the information to be displayed into a format suitable for the display 570. The display 470 can include any suitable display type, including but not limited to a cathode ray tube (CRT), a liquid crystal display (LCD), a plasma display, or the like.

The number and arrangement of components shown in FIG. 5 are provided as an example. In practice, there may be additional components, fewer components, different components, or differently arranged components than those shown in FIG. 5. Furthermore, two or more components shown in FIG. 5 may be implemented within a single component, or a single component shown in FIG. 5 may be implemented as multiple, distributed components. Additionally, or alternatively, a set of (one or more) components shown in FIG. 5 may perform one or more functions described as being performed by another set of components shown in FIG. 5.

The following provides an overview of some Aspects of the present disclosure:

Aspect 1: A method performed by an electronic device, comprising: detecting a start of a voltage ramp transition period associated with changing a voltage at which an integrated circuit operates from a first voltage to a second voltage, wherein changing the voltage from the first voltage to the second voltage causes changes to one or more parameters that impact performance associated with the integrated circuit during the voltage ramp transition period; triggering, responsive to detecting the start of the voltage ramp transition period, a dynamic calibration mode that compensates for the changes to the one or more parameters that impact the performance associated with the integrated circuit during the voltage ramp transition period; and exiting the dynamic calibration mode responsive to detecting an end of the voltage ramp transition period.

Aspect 2: The method of Aspect 1, wherein the dynamic calibration mode calibrates one or more impedance codes associated with one or more I/O devices as a function of the voltage at which the integrated circuit operates to compensate for the changes to the one or more parameters that impact the performance associated with the integrated circuit during the voltage ramp transition period.

Aspect 3: The method of Aspect 2, wherein the dynamic calibration mode adjusts values of the one or more impedance codes associated with the one or more I/O devices multiple times during the voltage ramp transition period.

Aspect 4: The method of Aspect 1, wherein the dynamic calibration mode adjusts values of the one or more parameters at periodic intervals during the voltage ramp transition period based on pre-calibrated values associated with one or more of the first voltage, the second voltage, or one or more intermediate voltages between the first voltage and the second voltage.

Aspect 5: The method of Aspect 4, wherein the one or more pre-calibrated values are stored in a lookup table.

Aspect 6: The method of any of Aspects 1-5, wherein the start and the end of the voltage ramp transition period are detected according to an indicator provided by a voltage sensor associated with the integrated circuit or a local measurement associated with the integrated circuit.

Aspect 7: The method of any of Aspects 1-6, wherein the start and the end of the voltage ramp transition period are detected according to a signal received from a component that controls a power management integrated circuit.

Aspect 8: The method of any of Aspects 1-7, wherein the start and the end of the voltage ramp transition period are detected according to a signal that relates to switching a frequency at which the integrated circuit operates from a first frequency to a second frequency.

Aspect 9: The method of any of Aspects 1-8, wherein the voltage ramp transition period is associated with increasing the voltage at which the integrated circuit operates from the first voltage to the second voltage.

Aspect 10: The method of any of Aspects 1-9, wherein the voltage ramp transition period is associated with reducing the voltage at which the integrated circuit operates from the first voltage to the second voltage.

Aspect 11: The method of any of Aspects 1-10, wherein the one or more parameters that are compensated as a function of the voltage during the voltage ramp transition period include one or more delays, one or more impedances, one or more reference voltages, a data eye width, or a data eye height.

Aspect 12: An electronic device for wireless communication, comprising: one or more memories; and one or more processors, coupled to the one or more memories, configured to cause the electronic device to: detect a start of a voltage ramp transition period associated with changing a voltage at which an integrated circuit operates from a first voltage to a second voltage, wherein changing the voltage from the first voltage to the second voltage causes changes to one or more parameters that impact performance associated with the integrated circuit during the voltage ramp transition period; trigger, responsive to detecting the start of the voltage ramp transition period, a dynamic calibration mode that compensates for the changes to the one or more parameters that impact the performance associated with the integrated circuit during the voltage ramp transition period; and exit the dynamic calibration mode responsive to detecting an end of the voltage ramp transition period.

Aspect 13: The electronic device of Aspect 12, wherein the dynamic calibration mode calibrates one or more impedance codes associated with one or more I/O devices as a function of the voltage at which the integrated circuit operates to compensate for the changes to the one or more parameters that impact the performance associated with the integrated circuit during the voltage ramp transition period.

Aspect 14: The electronic device of Aspect 13, wherein the dynamic calibration mode adjusts values of the one or more impedance codes associated with the one or more I/O devices multiple times during the voltage ramp transition period.

Aspect 15: The electronic device of Aspect 12, wherein the dynamic calibration mode adjusts values of the one or more parameters at periodic intervals during the voltage ramp transition period based on pre-calibrated values associated with one or more of the first voltage, the second voltage, or one or more intermediate voltages between the first voltage and the second voltage.

Aspect 16: The electronic device of Aspect 15, wherein the one or more pre-calibrated values are stored in a lookup table.

Aspect 17: The electronic device of any of Aspects 12-16, wherein the start and the end of the voltage ramp transition period are detected according to an indicator provided by a voltage sensor associated with the integrated circuit or a local measurement associated with the integrated circuit.

Aspect 18: The electronic device of any of Aspects 12-17, wherein the start and the end of the voltage ramp transition period are detected according to a signal received from a component that controls a power management integrated circuit.

Aspect 19: The electronic device of any of Aspects 12-18, wherein the start and the end of the voltage ramp transition period are detected according to a signal that relates to switching a frequency at which the integrated circuit operates from a first frequency to a second frequency.

Aspect 20: The electronic device of any of Aspects 12-19, wherein the voltage ramp transition period is associated with increasing the voltage at which the integrated circuit operates from the first voltage to the second voltage.

Aspect 21: The electronic device of any of Aspects 12-20, wherein the voltage ramp transition period is associated with reducing the voltage at which the integrated circuit operates from the first voltage to the second voltage.

Aspect 22: The method of any of Aspects 12-21, wherein the one or more parameters that are compensated as a function of the voltage during the voltage ramp transition period include one or more delays, one or more impedances, one or more reference voltages, a data eye width, or a data eye height.

Aspect 23: A non-transitory computer-readable medium storing a set of instructions for wireless communication, the set of instructions comprising: one or more instructions that, when executed by one or more processors of an electronic device, cause the electronic device to: detect a start of a voltage ramp transition period associated with changing a voltage at which an integrated circuit operates from a first voltage to a second voltage, wherein changing the voltage from the first voltage to the second voltage causes changes to one or more parameters that impact performance associated with the integrated circuit during the voltage ramp transition period; trigger, responsive to detecting the start of the voltage ramp transition period, a dynamic calibration mode that compensates for the changes to the one or more parameters that impact the performance associated with the integrated circuit during the voltage ramp transition period; and exit the dynamic calibration mode responsive to detecting an end of the voltage ramp transition period.

Aspect 24: The non-transitory computer-readable medium of Aspect 23, wherein the dynamic calibration mode calibrates one or more impedance codes associated with one or more I/O devices as a function of the voltage at which the integrated circuit operates to compensate for the changes to the one or more parameters that impact the performance associated with the integrated circuit during the voltage ramp transition period.

Aspect 25: The non-transitory computer-readable medium of any of Aspects 23-24, wherein the start and the end of the voltage ramp transition period are detected according to an indicator provided by a voltage sensor associated with the integrated circuit or a local measurement associated with the integrated circuit.

Aspect 26: The non-transitory computer-readable medium of any of Aspects 23-25, wherein the start and the end of the voltage ramp transition period are detected according to a signal received from a component that controls a power management integrated circuit.

Aspect 27: The non-transitory computer-readable medium of any of Aspects 22-26, wherein the start and the end of the voltage ramp transition period are detected according to a signal that relates to switching a frequency at which the integrated circuit operates from a first frequency to a second frequency.

Aspect 28: The non-transitory computer-readable medium of any of Aspects 23-27, wherein the voltage ramp transition period is associated with increasing or reducing the voltage at which the integrated circuit operates from the first voltage to the second voltage.

Aspect 29: An apparatus for wireless communication, comprising: means for detecting a start of a voltage ramp transition period associated with changing a voltage at which an integrated circuit operates from a first voltage to a second voltage, wherein changing the voltage from the first voltage to the second voltage causes changes to one or more parameters that impact performance associated with the integrated circuit during the voltage ramp transition period; means for triggering, responsive to detecting the start of the voltage ramp transition period, a dynamic calibration mode that compensates for the changes to the one or more parameters that impact the performance associated with the integrated circuit during the voltage ramp transition period; and means for exiting the dynamic calibration mode responsive to detecting an end of the voltage ramp transition period.

Aspect 30: The apparatus of Aspect 29, wherein the dynamic calibration mode calibrates one or more impedance codes associated with one or more I/O devices as a function of the voltage at which the integrated circuit operates to compensate for the changes to the one or more parameters that impact the performance associated with the integrated circuit during the voltage ramp transition period.

Aspect 31: The apparatus of any of Aspects 29-30, wherein the start and the end of the voltage ramp transition period are detected according to one or more of an indicator provided by a voltage sensor associated with the integrated circuit, a local measurement associated with the integrated circuit, a signal received from a component that controls a power management integrated circuit, or a signal that relates to switching a frequency at which the integrated circuit operates from a first frequency to a second frequency.

Aspect 32: The apparatus of any of Aspects 29-31, wherein the voltage ramp transition period is associated with increasing or reducing the voltage at which the integrated circuit operates from the first voltage to the second voltage.

Aspect 33: A system configured to perform one or more operations recited in one or more of Aspects 1-32.

Aspect 34: An apparatus comprising means for performing one or more operations recited in one or more of Aspects 1-32.

Aspect 35: A non-transitory computer-readable medium storing a set of instructions, the set of instructions comprising one or more instructions that, when executed by a device, cause the device to perform one or more operations recited in one or more of Aspects 1-32.

Aspect 36: A computer program product comprising instructions or code for executing one or more operations recited in one or more of Aspects 1-32.

The foregoing disclosure provides illustration and description but is not intended to be exhaustive or to limit the aspects to the precise forms disclosed. Modifications and variations may be made in light of the above disclosure or may be acquired from practice of the aspects.

As used herein, the term “component” is intended to be broadly construed as hardware and/or a combination of hardware and software. “Software” shall be construed broadly to mean instructions, instruction sets, code, code segments, program code, programs, subprograms, software modules, applications, software applications, software packages, routines, subroutines, objects, executables, threads of execution, procedures, and/or functions, among other examples, whether referred to as software, firmware, middleware, microcode, hardware description language, or otherwise. As used herein, a “processor” is implemented in hardware and/or a combination of hardware and software. It will be apparent that systems and/or methods described herein may be implemented in different forms of hardware and/or a combination of hardware and software. The actual specialized control hardware or software code used to implement these systems and/or methods is not limiting of the aspects. Thus, the operation and behavior of the systems and/or methods are described herein without reference to specific software code, since those skilled in the art will understand that software and hardware can be designed to implement the systems and/or methods based, at least in part, on the description herein.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various aspects. Many of these features may be combined in ways not specifically recited in the claims and/or disclosed in the specification. The disclosure of various aspects includes each dependent claim in combination with every other claim in the claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Furthermore, as used herein, the terms “set” and “group” are intended to include one or more items and may be used interchangeably with “one or more.” Where only one item is intended, the phrase “only one” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”).

What is claimed is:

1. A method performed by an electronic device, comprising:
detecting a start of a voltage ramp transition period associated with changing a voltage at which an integrated circuit operates from a first voltage to a second voltage, wherein changing the voltage from the first voltage to the second voltage causes changes to one or more parameters that impact performance associated with the integrated circuit during the voltage ramp transition period;
triggering, responsive to detecting the start of the voltage ramp transition period, a dynamic calibration mode that compensates for the changes to the one or more parameters that impact the performance associated with the integrated circuit during the voltage ramp transition period; and
exiting the dynamic calibration mode responsive to detecting an end of the voltage ramp transition period.

2. The method of claim 1, wherein the dynamic calibration mode calibrates one or more impedance codes associated with one or more input/output (I/O) devices as a function of the voltage at which the integrated circuit operates to compensate for the changes to the one or more parameters that impact the performance associated with the integrated circuit during the voltage ramp transition period.

3. The method of claim 2, wherein the dynamic calibration mode adjusts values of the one or more impedance codes associated with the one or more I/O devices multiple times during the voltage ramp transition period.

4. The method of claim 1, wherein the dynamic calibration mode adjusts values of the one or more parameters at periodic intervals during the voltage ramp transition period based on pre-calibrated values associated with one or more of the first voltage, the second voltage, or one or more intermediate voltages between the first voltage and the second voltage.

5. The method of claim 4, wherein the one or more pre-calibrated values are stored in a lookup table.

6. The method of claim 1, wherein the start and the end of the voltage ramp transition period are detected according to an indicator provided by a voltage sensor associated with the integrated circuit or a local measurement associated with the integrated circuit.

7. The method of claim 1, wherein the start and the end of the voltage ramp transition period are detected according to a signal received from a component that controls a power management integrated circuit.

8. The method of claim 1, wherein the start and the end of the voltage ramp transition period are detected according to a signal that relates to switching a frequency at which the integrated circuit operates from a first frequency to a second frequency.

9. The method of claim 1, wherein the voltage ramp transition period is associated with increasing the voltage at which the integrated circuit operates from the first voltage to the second voltage.

10. The method of claim 1, wherein the voltage ramp transition period is associated with reducing the voltage at which the integrated circuit operates from the first voltage to the second voltage.

11. The method of claim 1, wherein the one or more parameters that are compensated as a function of the voltage during the voltage ramp transition period include one or more delays, one or more impedances, one or more reference voltages, a data eye width, or a data eye height.

12. An electronic device for wireless communication, comprising:
one or more memories; and
one or more processors, coupled to the one or more memories, configured to cause the electronic device to:
detect a start of a voltage ramp transition period associated with changing a voltage at which an integrated circuit operates from a first voltage to a second voltage, wherein changing the voltage from the first voltage to the second voltage causes changes to one or more parameters that impact performance associated with the integrated circuit during the voltage ramp transition period;
trigger, responsive to detecting the start of the voltage ramp transition period, a dynamic calibration mode that compensates for the changes to the one or more parameters that impact the performance associated with the integrated circuit during the voltage ramp transition period; and
exit the dynamic calibration mode responsive to detecting an end of the voltage ramp transition period.

13. The electronic device of claim 12, wherein the dynamic calibration mode calibrates one or more impedance codes associated with one or more input/output (I/O) devices as a function of the voltage at which the integrated circuit operates to compensate for the changes to the one or more parameters that impact the performance associated with the integrated circuit during the voltage ramp transition period.

14. The electronic device of claim 13, wherein the dynamic calibration mode adjusts values of the one or more impedance codes associated with the one or more I/O devices multiple times during the voltage ramp transition period.

15. The electronic device of claim 12, wherein the dynamic calibration mode adjusts values of the one or more parameters at periodic intervals during the voltage ramp transition period based on pre-calibrated values associated with one or more of the first voltage, the second voltage, or one or more intermediate voltages between the first voltage and the second voltage.

16. The electronic device of claim 15, wherein the one or more pre-calibrated values are stored in a lookup table.

17. The electronic device of claim 12, wherein the start and the end of the voltage ramp transition period are detected according to an indicator provided by a voltage sensor associated with the integrated circuit or a local measurement associated with the integrated circuit.

18. The electronic device of claim 12, wherein the start and the end of the voltage ramp transition period are detected according to a signal received from a component that controls a power management integrated circuit.

19. The electronic device of claim 12, wherein the start and the end of the voltage ramp transition period are detected according to a signal that relates to switching a frequency at which the integrated circuit operates from a first frequency to a second frequency.

20. The electronic device of claim 12, wherein the voltage ramp transition period is associated with increasing the voltage at which the integrated circuit operates from the first voltage to the second voltage.

21. The electronic device of claim 12, wherein the voltage ramp transition period is associated with reducing the voltage at which the integrated circuit operates from the first voltage to the second voltage.

22. The electronic device of claim 12, wherein the one or more parameters that are compensated as a function of the voltage during the voltage ramp transition period include one or more delays, one or more impedances, one or more reference voltages, a data eye width, or a data eye height.

23. A non-transitory computer-readable medium storing a set of instructions for wireless communication, the set of instructions comprising:
one or more instructions that, when executed by one or more processors of an electronic device, cause the electronic device to:
detect a start of a voltage ramp transition period associated with changing a voltage at which an integrated circuit operates from a first voltage to a second voltage, wherein changing the voltage from the first voltage to the second voltage causes changes to one or more parameters that impact performance associated with the integrated circuit during the voltage ramp transition period;
trigger, responsive to detecting the start of the voltage ramp transition period, a dynamic calibration mode that compensates for the changes to the one or more parameters that impact the performance associated with the integrated circuit during the voltage ramp transition period; and
exit the dynamic calibration mode responsive to detecting an end of the voltage ramp transition period.

24. The non-transitory computer-readable medium of claim 23, wherein the dynamic calibration mode calibrates one or more impedance codes associated with one or more input/output (I/O) devices as a function of the voltage at which the integrated circuit operates to compensate for the changes to the one or more parameters that impact the performance associated with the integrated circuit during the voltage ramp transition period.

25. The non-transitory computer-readable medium of claim 23, wherein the start and the end of the voltage ramp transition period are detected according to an indicator provided by a voltage sensor associated with the integrated circuit or a local measurement associated with the integrated circuit.

26. The non-transitory computer-readable medium of claim 23, wherein the start and the end of the voltage ramp transition period are detected according to a signal received from a component that controls a power management integrated circuit.

27. The non-transitory computer-readable medium of claim 23, wherein the start and the end of the voltage ramp transition period are detected according to a signal that relates to switching a frequency at which the integrated circuit operates from a first frequency to a second frequency.

28. An apparatus for wireless communication, comprising:
means for detecting a start of a voltage ramp transition period associated with changing a voltage at which an integrated circuit operates from a first voltage to a second voltage, wherein changing the voltage from the first voltage to the second voltage causes changes to one or more parameters that impact performance associated with the integrated circuit during the voltage ramp transition period;
means for triggering, responsive to detecting the start of the voltage ramp transition period, a dynamic calibration mode that compensates for the changes to the one or more parameters that impact the performance associated with the integrated circuit during the voltage ramp transition period; and
means for exiting the dynamic calibration mode responsive to detecting an end of the voltage ramp transition period.

29. The apparatus of claim 28, wherein the dynamic calibration mode calibrates one or more impedance codes associated with one or more input/output (I/O) devices as a function of the voltage at which the integrated circuit operates to compensate for the changes to the one or more parameters that impact the performance associated with the integrated circuit during the voltage ramp transition period.

30. The apparatus of claim 28, wherein the start and the end of the voltage ramp transition period are detected according to one or more of an indicator provided by a voltage sensor associated with the integrated circuit, a local measurement associated with the integrated circuit, a signal received from a component that controls a power management integrated circuit, or a signal that relates to switching a frequency at which the integrated circuit operates from a first frequency to a second frequency.
